(19) United States
(12) Patent Application Publication
(10) Pub. No.: US 2026/0072116 A1
(43) Pub. Date: Mar. 12, 2026

(54) CORRECTING AN INTENSITY INHOMOGENEITY IN A MAGNETIC RESONANCE REPRESENTATION

(71) Applicant: Siemens Healthineers AG, Forchheim (DE)

(72) Inventors: Till Hülnhagen, Erlangen (DE); Patrick Liebig, Erlangen (DE); David Grodzki, Erlangen (DE); Tobias Krieg, Fürth (DE)

(21) Appl. No.: 19/323,316

(22) Filed: Sep. 9, 2025

(30) Foreign Application Priority Data
Sep. 11, 2024 (DE) 10 2024 208 633.9

(51) Int. Cl. G01R 33/565; G01R 33/341; G01R 33/56

(52) U.S. Cl. CPC G01R 33/5659; G01R 33/341; G01R 33/5608

(57) ABSTRACT

A method for generating am intensity-corrected magnetic resonance representation. In this method, reference measurement data is provided, wherein at least part of the reference measurement data is generated from magnetic resonance signals acquired by at least one receive antenna of at least one local coil by a magnetic resonance apparatus in accordance with a reference magnetic resonance sequence. In addition, image measurement data is provided, which is generated from magnetic resonance signals acquired by the at least one receive antenna of the least one local coil by the magnetic resonance apparatus in accordance with an image magnetic resonance sequence. A function trained by a machine learning algorithm is applied to the reference measurement data and the image measurement data as input data of the trained function. Correction data is provided from output data of the trained function, wherein the correction data describes an instrumentation-induced intensity inhomogeneity of the image measurement data. An intensity-corrected magnetic resonance representation is generated on the basis of the image measurement data and the correction data.

### CROSS REFERENCE TO RELATED APPLICATIONS

This application claims the benefit of DE 10 2024 208 633.9 filed on Sep. 11, 2024, which is hereby incorporated by reference in its entirety.

### FIELD

Embodiments relate to a method for generating an intensity-corrected magnetic resonance representation, to a method for providing a trained function for the output of correction data, to a generation unit for generating an intensity-corrected magnetic resonance representation, and to a computer program product.

### BACKGROUND

In medical technology, high soft-tissue contrasts are a particular feature of imaging using magnetic resonance (MR), also known as magnetic resonance imaging (MRI) or magnetic resonance tomography (MRT). In this process, an object under examination, for example a patient, is positioned in an examination space of a magnetic resonance apparatus. During a magnetic resonance measurement, radiofrequency (RF) pulses are radiated into the object under examination usually by a transmit coil arrangement of the magnetic resonance apparatus. In addition, gradient pulses are output by a gradient coil of the magnetic resonance apparatus to produce temporary magnetic field gradients in the examination space. The generated pulses excite nuclear spins in the object under examination. Spatially encoded magnetic resonance signals are released by relaxation of the excited nuclear spins. The released magnetic resonance signals are received by a receive coil arrangement, which may include one or more receive antennas, of the magnetic resonance apparatus and used to reconstruct magnetic resonance representations.

Instrumentation-induced, for example acquisition-induced and/or apparatus-induced, intensity inhomogeneities in magnetic resonance representations are a known problem for which no satisfactory solution has yet been found. They may be induced, inter alia, by spatially varying sensitivities of the receive antennas that are used to measure the magnetic resonance signals. Such intensity inhomogeneities may make an accurate diagnosis more difficult. It is therefore an aim to cancel out, or at least reduce as far as possible, such inhomogeneities by suitable methods.

The publication Tustison N J, Avants B B, Cook P A, Zheng Y, Egan A, Yushkevich P A, Gee J C. N4ITK: improved N3 bias correction. IEEE Trans Med Imaging. 2010 June; 29(6): 1310-20. doi: 10.1109/TMI.2010.2046908. Epub 2010 Apr. 8. PMID: 20378467; PMCID: PMC3071855 discloses a method for correcting image inhomogeneities.

### BRIEF SUMMARY AND DESCRIPTION

The scope of the embodiments is defined solely by the appended claims and is not affected to any degree by the statements within this summary. The present embodiments may obviate one or more of the drawbacks or limitations in the related art. Independent of the grammatical term usage, individuals with male, female or other gender identities are included within the term.

Embodiments generate magnetic resonance representations that exhibit a minimum possible instrumentation-induced intensity inhomogeneity.

A computer-implemented method for generating an intensity-corrected magnetic resonance representation is provided. In the method, reference measurement data is provided, wherein at least part of the reference measurement data is generated from magnetic resonance signals acquired by at least one receive antenna of at least one local coil by a magnetic resonance apparatus in accordance with a reference magnetic resonance sequence. In addition, image measurement data is provided, which is generated from magnetic resonance signals acquired by the at least one receive antenna of the least one local coil by the magnetic resonance apparatus in accordance with an image magnetic resonance sequence. A function trained by a machine learning algorithm is applied to the reference measurement data and the image measurement data as input data of the trained function. Correction data is provided from output data of the trained function, wherein the correction data describes an instrumentation-induced intensity inhomogeneity of the image measurement data. An intensity-corrected magnetic resonance representation is generated on the basis of the image measurement data and the correction data.

The acquired magnetic resonance signals may be magnetic resonance signals that were acquired for the examination of an object under examination, for example a patient, by the magnetic resonance apparatus.

The part of the reference measurement data that is generated from magnetic resonance signals acquired by the at least one receive antenna of the least one local coil by the magnetic resonance apparatus in accordance with the reference magnetic resonance sequence is also referred to below as local-coil reference measurement data.

The at least one receive antenna of the at least one local coil may include a plurality of receive antennas. The plurality of receive antennas may be distributed across a plurality of local coils. The at least one local coil may include a plurality of local coils, each having one or more receive antennas. For example, the at least one local coil includes two local coils, each having one receive antenna.

Stronger instrumentation-induced intensity inhomogeneities may arise especially when there are a plurality of receive antennas, and therefore correcting the magnetic resonance representation is particularly effective in this case.

The instrumentation-induced intensity inhomogeneity of the image measurement data may be caused for example by an inhomogeneous distribution of a B1 field that is present during the acquisition of the magnetic resonance signals in accordance with the reference magnetic resonance sequence and/or the image magnetic resonance sequence.

During the acquisition, for example an RF pulse, for example an RF transmit pulse, produces an alternating magnetic field known as a B1+ field in an examination region, in which the patient is located during the magnetic resonance measurement. The B1+ field therefore usually constitutes a distribution of the transmit field. A B1− field may describe a distribution of a receive field. The effective transmit-receive field may also be called the B1 field.

The method may take place in position space. The reference measurement data, image measurement data and/or the magnetic resonance representation may be position space data (data in position space), for example a position space representation (representation in position space). Position space may also be referred to as image space. Position space differs for example from k-space, that may also be referred to as the frequency domain.

Position space may describe a space in which a spatial distribution of nuclear magnetic resonance is depicted. Position space may be regarded as the result of a conversion of the measured magnetic resonance signals in k-space (raw data), that contain the frequency components of the signals. A transformation from position space into k-space (and vice versa) may be performed by a Fourier transform, for example.

Position space may be a real, for example geometric, space. For example, position space may be spanned by a two-dimensional or three-dimensional coordinate system, the coordinate axes of which are spatial axes, for instance an x-axis, y-axis and or z-axis. These are orthogonal axes, for example. Position space may be described by a coordinate system that defines the location and orientation of the object under examination in the magnetic field of the magnetic resonance apparatus.

The reference measurement data and the image measurement data may be, for example, data that is transformed from the magnetic resonance signals (as raw data) by a transform, for example a Fourier transform, into position space. The reference measurement data may include for example at least one reference representation and/or at least one reference image. The image measurement data may include for example at least one (diagnostic) representation and/or at least one (diagnostic) image.

The reference measurement data or the magnetic resonance signals that are the basis thereof may be acquired as part of one or more preliminary measurements before the (actual) main measurement. The image measurement data or the magnetic resonance signals that are the basis thereof may be acquired as part of the (actual) main measurement.

The reference magnetic resonance sequence may be a magnetic resonance sequence that differs from the image magnetic resonance sequence. A magnetic resonance sequence may include for example a temporal series of magnetic resonance pulses, that are generated by the magnetic resonance apparatus. Possible magnetic resonance pulses are RF pulses and/or gradient pulses. The image magnetic resonance sequence is a T2-weighted spin echo sequence, for example.

The at least one local coil may be part of a receive coil arrangement of the magnetic resonance apparatus. The at least one local coil may include a plurality of local coils. The receive antennas include, for example, electrically conductive loops suitable for receiving the magnetic resonance signals. A local coil may include, for example, one, two, four, eight, 16 or 32 receive antennas. The local coil is configured to be arranged directly on the object under examination, for example a patient, from which the magnetic resonance representation is generated. Advantageously, by arranging the local coil close to the patient, magnetic resonance signals may be received that have a high signal-to-noise ratio.

If the at least one receive antenna includes a plurality of receive antennas, these may be spatially distributed across the at least one local coil, i.e. they are situated at different locations on the at least one local coil. The plurality of receive antennas may have a different sensitivity, for example sensitivity distribution, for receiving the magnetic resonance signals. The sensitivity of a receive antenna may depend for example on its location and/or orientation relative to the patient and/or magnetic field. The different sensitivity, for example sensitivity distribution, of the plurality of receive antennas may lead for example to the instrumentation-induced intensity inhomogeneity of the image measurement data. Advantageously, the instrumentation-induced intensity inhomogeneity of the image measurement data may be corrected by the correction data.

The instrumentation-induced intensity inhomogeneity may be an intensity inhomogeneity caused by specific conditions during the acquisition of the magnetic resonance signals in accordance with the reference magnetic resonance sequence and/or the image magnetic resonance sequence. These conditions may be present for example as a result of the patient under examination who is being represented by the magnetic resonance representation. For example, the instrumentation-induced intensity inhomogeneity may include an anatomically induced intensity inhomogeneity, for example induced by an anatomy of the patient. The instrumentation-induced intensity inhomogeneity may be caused for example by a specific load on the at least one receive antenna, for example induced by the specific anatomy of the patient, during the acquisition of the magnetic resonance signals in accordance with the reference magnetic resonance sequence and/or the image magnetic resonance sequence. In addition, the instrumentation-induced intensity inhomogeneity may be caused by the instrumentation used for the acquisition of the magnetic resonance signals in accordance with the reference magnetic resonance sequence and/or the image magnetic resonance sequence, for example the type and arrangement of the local coil on the patient and/or other instrumentation factors.

The correction data may include for example a correction map. The correction map may include for example a spatial distribution of correction values, for example correction factors. Advantageously, the instrumentation-induced intensity inhomogeneity may be compensated on the basis of the correction data.

The correction data may be in the form of a matrix, for example a correction matrix. The image measurement data may also in the form of a matrix, for example an image matrix. Each element of the image matrix may correspond to a voxel of the intensity-corrected magnetic resonance representation. The size of the correction matrix may be equal to the size of the image matrix. Each element of the correction matrix has a value, for example a scaling factor, which in the generation of the intensity-corrected magnetic resonance representation is multiplied by the corresponding value in the image matrix.

The machine learning algorithm may be based on statistical algorithms, for example learning algorithms. The machine learning algorithm may map predefined training data onto a mathematical model, that it adapts to the training data such that it may generalize from this data to new cases. This process may be called training. After the training, the solution path found is advantageously stored in the model. The trained model may make predictions for new data, for example reference measurement data and/or image measurement data as input data, for example generate correction data as output data.

By using the image measurement data in addition to the reference measurement data as input data to the trained function, the trained function is provided with additional information, on the basis of which anatomically induced and instrumentation-induced signal inhomogeneities may advantageously be better distinguished. Thus advantageously, instrumentation-induced inhomogeneities may be corrected, and anatomically induced inhomogeneities may remain unaffected. Advantageously, it is possible to reduce the risk of, for example, spatially slowly varying fluctuations in image intensity that are actually induced by the anatomy being identified incorrectly as inhomogeneities induced by the acquisition technology and (erroneously) corrected.

An embodiment of the method provides that at least one (further) part of the reference measurement data is generated from magnetic resonance signals acquired by at least one receive antenna of a body coil, for example whole body coil, that is fixedly integrated in the magnetic resonance apparatus. In order to distinguish it from the local-coil reference measurement data, the reference measurement data acquired by the at least one receive antenna of the body coil that is fixedly integrated in the magnetic resonance apparatus is also referred to below as body-coil reference measurement data.

Advantageously, body coils that are fixedly integrated in the magnetic resonance apparatus have a largely homogeneous receive field. Advantageously, the size, geometry and/or arrangement of the antennas of the body coil and/or the positioning of such a body coil in the magnetic resonance apparatus means that its receive field is largely homogeneous.

The body-coil reference measurement data may advantageously be used as reference data for a homogeneous receive field. A sensitivity distribution of the at least one receive antenna of the at least one local coil may be derived advantageously from a comparison of the local-coil reference measurement data with the body-coil reference measurement data. For example, information about each receive field of the at least one receive antennas of the at least one local coil may be obtained therefrom.

An embodiment of the method provides that the reference magnetic resonance sequence is configured to bring about a neutral contrast, for example image contrast, in the reference measurement data.

A neutral contrast may be understood to mean here for example a contrast, for example an image contrast, that is not dominated by relaxation. For example, the neutral contrast is an image contrast that has a minimum possible specific weighting, for instance T1 weighting or T2 weighting. Advantageously, measurement data acquired with neutral contrast has the property that intensity differences in the images acquired by different receive antennas contain as far as possible only effects that may be attributed to the antenna sensitivities and/or other instrumentation-induced effects.

The neutral contrast may be a contrast that has a proton density weighting. Advantageously, in a proton density weighted magnetic resonance representation, the contrast is mainly influenced by the proton density of the tissue being represented. T1 and T2 effects are advantageously suppressed.

An embodiment of the method provides that the image measurement data has an image coordinate system (for example in position space), and that initial reference measurement data, for example initial local-coil reference measurement data and/or body-coil reference measurement data, is provided that has a reference coordinate system (for example in position space). In order to provide, for example generate, the reference measurement data, the initial reference measurement data is transformed from the reference coordinate system into the image coordinate system. This may be a transformation between two position spaces.

For example, the reference measurement is transformed into the same space as the image measurement. The reference measurement data advantageously covers a comparatively large volume, and any slices in the reference measurement data are often orientated along the gradient axes. For the image magnetic resonance sequence (the actual imaging sequence), a certain slice direction and/or geometry, that are matched to the anatomy and position of the patient, are advantageously used. In order to correct the image measurement data acquired in this way, the reference measurement data is advantageously transformed into the corresponding coordinate system of the image measurement data. Such a transformation may include, for example, matrix multiplication, interpolation of the reference measurement data, and/or cropping, for example volumetric cropping, of the reference measurement data.

An embodiment of the method provides that the reference measurement data, for example the local-coil reference measurement data, is combined data, that is combined from individual measurement data, in each case (individually) acquired by the at least one receive antenna of the at least one local coil by the magnetic resonance apparatus in accordance with the reference magnetic resonance sequence. Advantageously, combined local-coil reference measurement data, for example a combined local-coil reference image, allows simpler, for example less computationally intensive, generation of the correction data and/or of the intensity-corrected magnetic resonance representation.

An embodiment of the method provides that the trained function is based on a neural network, for example a convolutional neural network (CNN). Advantageously, convolutional neural networks are particularly good at processing image data such as the reference measurement data and/or the image measurement data.

For example, the trained function is based on a U-net. A U-net preferably includes a network having a contraction path and an expansion path. In the contraction path, spatial information is usually reduced, whereas feature information is increased, and in the expansion path, feature information and the spatial information are recombined. This may advantageously increase the resolution of the output data.

In addition, a computer-implemented method is proposed for providing a trained function for the output of correction data. In this method, training reference measurement data is provided, wherein at least part of the training reference measurement data, for example local-coil training reference measurement data, is generated from magnetic resonance signals acquired by at least one receive antenna of at least one local coil by a magnetic resonance apparatus. Optionally, body-coil training reference measurement data is additionally provided as a further part of the training reference measurement data, wherein the body-coil training reference measurement data is generated from magnetic resonance signals acquired by at least one receive antenna of a body coil, that is fixedly integrated in the magnetic resonance apparatus. In addition, training image measurement data is provided, wherein the training image measurement data is generated from magnetic resonance signals acquired by the at least one receive antenna of the at least one local coil by the magnetic resonance apparatus. In addition, training target image measurement data (ground truth data) is provided, wherein the training target image measurement data is training image measurement data corrected by a correction algorithm. The trained function is trained on the basis of the training reference measurement data, for example the local-coil training reference measurement data and optionally the body-coil training reference measurement data, and the training image measurement data (as training input data) and the training target image measurement data (as training output data). The function trained thereby for the output of correction data is ultimately provided.

The training of the trained function may include for example iterative minimization of a loss function on the basis of the provided training reference measurement data, the provided training image measurement data and the provided training target image measurement data.

For example, the loss function may have the following form: loss function=mean value (estimated correction data*training image measurement data−training target image measurement data)². The loss function constitutes, for example, the root mean square of estimated correction data multiplied by the training image measurement data minus the training target image measurement data.

The estimated correction data may include, for example be, an estimated correction map, for example. The neural network may estimate initially a correction map. The training image measurement data may constitute an uncorrected magnetic resonance representation.

This method for providing the trained function preferably involves supervised machine learning. The machine learning algorithm in this case is presented with a dataset containing training target image measurement data as already known target variables. Advantageously, the algorithm learns relationships and/or dependencies in the data that explain these target variables.

The providing of the training reference measurement data may be performed in a similar way to the providing of the reference measurement data. The providing of the training image measurement data may be performed in a similar way to the providing of the image measurement data. The features disclosed for the method for generating an intensity-corrected magnetic resonance representation may be transferred correspondingly to the training reference measurement data and/or the training image measurement data.

The possible correction algorithms include, for example, image filtering algorithms, that determine inhomogeneities on the basis of the measured training image measurement data, or signal processing processes in which general measurements using different receive antennas are carried out, and inhomogeneities and corresponding correction factors are determined therefrom.

Training target image measurement data is provided, for example, by the correction algorithm disclosed in the publication Tustison N J, Avants B B, Cook P A, Zheng Y, Egan A, Yushkevich P A, Gee J C. N4ITK: improved N3 bias correction. IEEE Trans Med Imaging. 2010 June; 29(6):1310-20. doi: 10.1109/TMI.2010.2046908. Epub 2010 Apr. 8. PMID: 20378467; PMCID: PMC3071855. This is an image filtering algorithm that, on the basis of the measured training image measurement data, may determine and cancel out inhomogeneities. The N4ITK algorithm replaces the B-spline smoothing component of the N3 algorithm with an alternative B-spline approximation method, that is faster, more robust and more flexible. Furthermore, they modify the iterative optimization scheme to allow incremental updating of a bias field estimator. A person skilled in the art knows numerous further possible correction algorithms, and therefore the embodiments are not restricted to the use of the aforementioned correction algorithm.

In addition, a (previously described) computer-implemented method for generating an intensity-corrected magnetic resonance representation is provided, wherein the trained function is provided according to a (previously described) computer-implemented method for providing the trained function.

Furthermore, a generation unit for generating an intensity-corrected magnetic resonance representation is proposed. This includes a first input interface for receiving reference measurement data, wherein at least part of the reference measurement data is generated from magnetic resonance signals acquired by at least one receive antenna of at least one local coil by a magnetic resonance apparatus. In addition, the generation unit includes a second input interface for receiving image measurement data, wherein the image measurement data is generated from magnetic resonance signals acquired by the at least one receive antenna of the least one local coil by the magnetic resonance apparatus. Furthermore, the generation unit includes an output interface for the output of correction data. In addition, the generation unit includes a calculation unit for applying a trained function to the reference measurement data and the image measurement data, wherein the correction data is generated as output data.

Optionally, the generation unit includes a third input interface for receiving further reference measurement data, that is generated from magnetic resonance signals acquired by at least one receive antenna of a body coil, that is fixedly integrated in the magnetic resonance apparatus.

The advantages of the generation unit for generating an intensity-corrected magnetic resonance representation are essentially the same as the advantages of the computer-implemented method for generating an intensity-corrected magnetic resonance representation, which advantages are explained in detail above. Features, advantages or alternative embodiments mentioned in this connection may also be applied to the other claimed subject matter, and vice versa.

In other words, the claims relating to physical objects may also be developed by combining with the features described or claimed in connection with a method. The corresponding functional features of the method are embodied in this case by corresponding physical modules, for example by hardware modules.

A computer program product is also provided, that includes a program and may be loaded directly into a memory of a programmable generation unit for generating an intensity-corrected magnetic resonance representation, and has program code, for example libraries and auxiliary functions, in order to execute a proposed method when the computer program product is executed in the generation unit. The computer program product may include software containing a source code, that still needs to be compiled and linked or just needs to be interpreted, or an executable software code, that for execution only needs to be loaded into the system control unit.

The proposed method may advantageously be performed quickly, reproducibly and robustly by the computer program product. The computer program product may be configured such that it may perform the proposed method steps by the generation unit. The system control unit has the necessary specification such as, for example, a suitable RAM, a suitable graphics card or a suitable logic unit, in order to be able to execute the respective method steps efficiently.

The computer program product is stored, for example, on a computer-readable medium or on a network or server, from where it may be loaded into the processor of a local generation unit. In addition, control information of the computer program product may be stored on an electronically readable data storage medium. Examples of electronic readable data storage media are a hard disk, an SSD, a DVD, a magnetic tape or a USB stick, on which is stored electronically readable control information, for example software. When this control information is read from the data storage medium and stored in a generation unit, all the proposed embodiments of the above-described methods for generating an intensity-corrected magnetic resonance representation may be performed.

In addition, a training system is provided including a first training interface, that is configured to receive training reference measurement data, wherein at least part of the training reference measurement data is generated from magnetic resonance signals acquired by at least one receive antenna of at least one local coil by a magnetic resonance apparatus. In addition, the training system includes a second training interface, that is configured to receive training image measurement data, wherein at least part of the training image measurement data is generated from magnetic resonance signals acquired by the at least one receive antenna of the at least one local coil by the magnetic resonance apparatus. Furthermore, the training system includes a third training interface, that is configured to receive training target image measurement data, wherein the training target image measurement data is training image measurement data corrected by a correction algorithm. In addition, the training system includes a training calculation unit, that is configured to train the trained function on the basis of the training reference measurement data and the training image measurement data as the training input data and the training target image measurement data as the training output data. Furthermore, the training system includes a fourth training interface, that is configured to provide the trained function for the output of the correction data.

### BRIEF DESCRIPTION OF THE FIGURES

Further advantages, features and details appear in the embodiments described below and follow from the drawings. Corresponding parts are denoted by the same reference signs in all the figures.

FIG. 1 depicts a magnetic resonance apparatus having a generation unit for generating an intensity-corrected magnetic resonance representation according to an embodiment.

FIG. 2 depicts a diagram of a method for generating an intensity-corrected magnetic resonance representation according to an embodiment.

FIG. 3 depicts a diagram of an extended method for generating an intensity-corrected magnetic resonance representation according to an embodiment.

FIG. 4 depicts a diagram of a convolutional neural network for providing correction data according to an embodiment.

FIG. 5 depicts a diagram of a method for providing a trained function for the output of correction data according to an embodiment.

FIG. 6 depicts a generation unit for generating an intensity-corrected magnetic resonance representation according to an embodiment.

### DETAILED DESCRIPTION

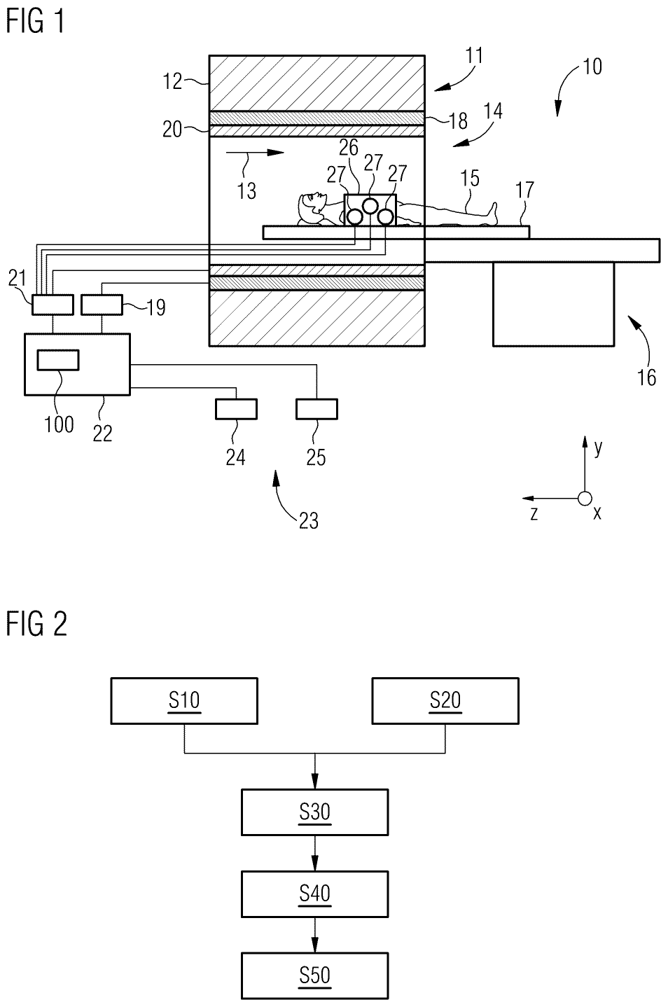

FIG. 1 depicts schematically a magnetic resonance apparatus 10. The magnetic resonance apparatus 10 includes a magnet unit 11, that includes a main magnet 12 for producing a powerful main magnetic field 13, that for example is constant over time. The magnetic resonance apparatus 10 also includes a patient placement region 14 for accommodating a patient 15. In the present embodiment, the patient placement region 14 is shaped as a cylinder and is enclosed in a circumferential direction cylindrically by the magnet unit 11. The patient placement region 14 may have a different design. The patient 15 may be moved into the patient placement region 14 by a patient positioning apparatus 16 of the magnetic resonance apparatus 10. The patient positioning apparatus 16 includes for this purpose a patient couch 17, that is configured to be able to move inside the patient placement region 14.

The magnet unit 11 further includes a gradient coil 18 for producing magnetic field gradients, that are used for spatial encoding during imaging. The gradient coil 18 is controlled by a gradient control unit 19 of the magnetic resonance apparatus 10. The magnet unit 11 also includes a body coil 20, that is fixedly integrated in the magnetic resonance apparatus 10. The body coil 20 is controlled by a radiofrequency antenna control unit 21 of the magnetic resonance apparatus 10 and radiates radiofrequency magnetic resonance sequences into an examination space, that is largely formed by a patient placement region 14 of the magnetic resonance apparatus 10. This results in excitation of atomic nuclei in the main magnetic field 13 produced by the main magnet 12. Magnetic resonance signals are produced by relaxation of the excited atomic nuclei. The body coil 20 is configured to receive the magnetic resonance signals. The magnetic resonance apparatus also includes a local coil 26, that is arranged directly on the patient 15. It includes a plurality of receive antennas 27 for receiving the magnetic resonance signals. The receive antennas 27 are spatially distributed across the local coil or across the patient 15 and each have a particular sensitivity for receiving the magnetic resonance signals. For example, a receive channel may be assigned to each of the plurality of receive antennas 27.

The magnetic resonance apparatus 10 includes a system control unit 22 for controlling the main magnet 12, the gradient control unit 19 and the radiofrequency antenna control unit 21. The system control unit 22 centrally controls the magnetic resonance apparatus 10, for instance implementing a predetermined imaging gradient echo sequence. In addition, the system control unit 22 includes a generation unit 100 for generating an intensity-corrected magnetic resonance representation. Thus the generation unit 100 may be part of a magnetic resonance apparatus 100. It is also conceivable, however, that the generation unit 100 is independent of a magnetic resonance apparatus 10. For example, it is conceivable that the generation unit 100 is connected to the magnetic resonance apparatus 10 by a network.

In addition, the magnetic resonance apparatus 10 includes a user interface 23, that is connected to the system control unit 22. Control information such as imaging parameters, for instance, and reconstructed magnetic resonance representations may be displayed to a medical operator on a display unit 24, for example on at least one monitor, of the user interface 23. In addition, the user interface 23 includes an input unit 25, that may be used by the medical operator to enter information and/or parameters during a measurement process. The axes x, y and z span the position space in which the magnetic resonance apparatus 10 and the patient 15 are located.

FIG. 2 depicts a computer-implemented method for generating an intensity-corrected magnetic resonance representation, which method may be executed for example by the generation unit 100.

In S10, reference measurement data is provided. At least part of the reference measurement data is generated from magnetic resonance signals acquired by the plurality of receive antennas 27 of the local coil 26 by the magnetic resonance apparatus 10 in accordance with a reference magnetic resonance sequence. The reference magnetic resonance sequence may be configured to bring about a neutral contrast in the reference measurement data.

In S20, image measurement data is provided. The image measurement data is generated from magnetic resonance signals acquired by the plurality of receive antennas 27 of the local coil 26 by the magnetic resonance apparatus 10 in accordance with an image magnetic resonance sequence.

In S30, a trained function is applied to the reference measurement data and the image measurement data as input data of the trained function. The trained function is based on a machine learning algorithm.

In S40, correction data is provided as output data of the trained function. The correction data describes an instrumentation-induced intensity inhomogeneity of the image measurement data, for example induced by apparatus (for example by the magnetic resonance apparatus 10), and/or induced by a load on the receive antennas 27.

In S50, an intensity-corrected magnetic resonance representation is generated on the basis of the image measurement data and the correction data. The generated magnetic resonance representation may be displayed by the display unit 24, for example.

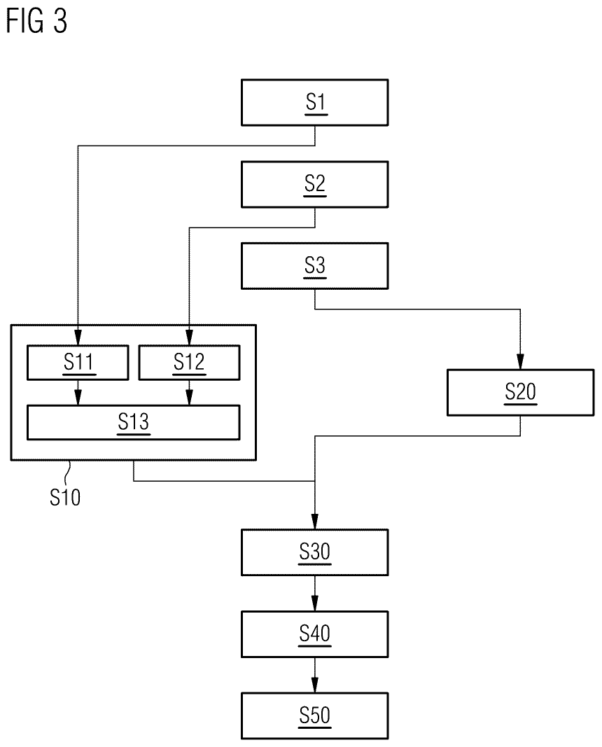

FIG. 3 depicts an extended method, wherein the additional possible aspects of the method are discussed below. Thus in S1, the plurality of receive elements 27 of the local coil 26 are used to acquire magnetic resonance signals, from which local-coil reference measurement data is generated as part of the reference measurement data. These magnetic resonance signals are acquired using a local-coil reference magnetic resonance sequence.

In S2, the body coil 20 is used to acquire magnetic resonance signals, from which local-coil reference measurement data is generated as part of the reference data. These magnetic resonance signals are acquired using a body-coil reference magnetic resonance sequence.

In S3, the plurality of receive elements 27 of the local coil 26 are used to acquire magnetic resonance signals, from which image measurement data is generated.

The generating of the measurement data (i.e. the reference measurement data, for example the local-coil reference measurement data and/or the body-coil reference measurement data, and/or the image measurement data) may include for example a transformation of the magnetic resonance signals (as raw data) in k-space into measurement data in position space. The measurement data may be in the form of image data. For example, the measurement data has in each case a plurality of image points, each assigned an image value, for example an intensity value. For example, the image points lie in position space.

The magnetic resonance signals received by the respective receive antennas 27 of the local coil may exist as separate individual measurement data. The individual measurement data may be combined into the reference measurement data, for example into the local-coil reference measurement data, i.e. the reference measurement data, for example the local-coil reference measurement data, is combined data. If the body coil also has a plurality of receive coils, the separate individual measurement data that these acquire is likewise combined before the further processing.

The acquisition of the magnetic resonance signals in S1 and/or S2 may take place, for example, as part of calibration measurements (that precede the acquisition of the magnetic resonance signals in S3). Advantageously, the method for generating an intensity-corrected magnetic resonance representation draws on measurement data that is acquired anyway as part of the magnetic resonance examination.

The providing of the reference measurement data in S10 here includes providing the local-coil reference measurement data in S11 and (optionally) providing the body-coil reference measurement data in S12.

The image measurement data provided in S20 includes an image coordinate system. For example, the reference measurement data provided in S11 and S12 constitutes initial (preliminary) reference measurement data, that has a reference coordinate system. Advantageously, in S13, the initial reference measurement data is transformed from the reference coordinate system into the image coordinate system.

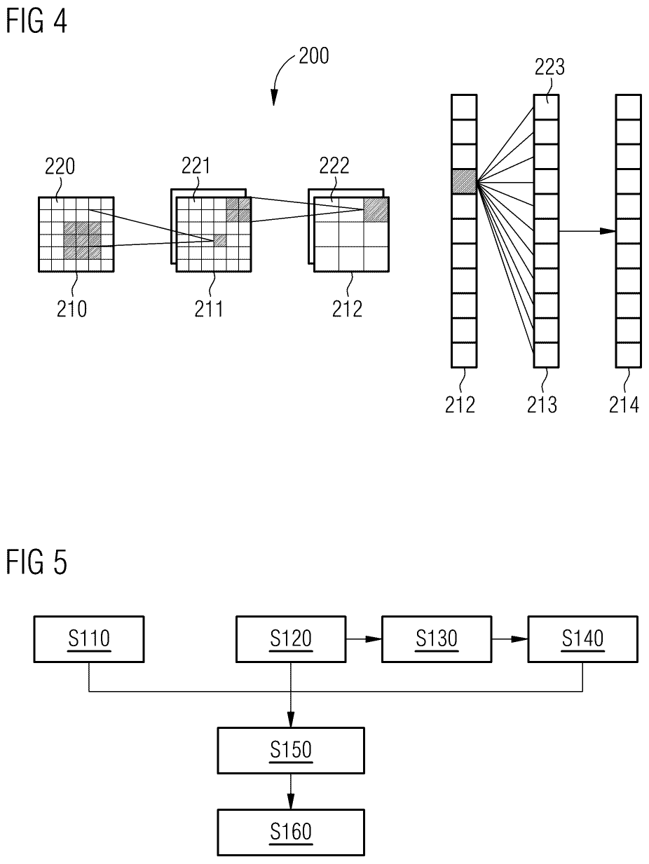

FIG. 4 depicts by way of example a convolutional neural network (CNN) on which the trained function applied in S30 is based. In the embodiment shown, the convolutional neural network 200 comprises an input layer 210, a convolutional layer 211, a pooling layer 212, a fully interconnected layer 213, and an output layer 214. Alternatively, the convolutional neural network 200 may include a plurality of convolutional layers 211, a plurality of pooling layers 212 and a plurality of fully interconnected layers 213 and also other types of layers. The layers can be chosen to have any order, although fully interconnected layers 213 usually form the last layers before the output layer 214.

For example, within a convolutional neural network 200, the nodes 220, . . . , 224 in a layer 210, . . . , 214 can be viewed for example as arranged as a d-dimensional matrix or as a d-dimensional image. For example, in the two-dimensional case, the value of the node 220, . . . , 224 with indices i and j in the n-th layer 210, . . . , 214 can be denoted by x(n)[i,j]. The arrangement of the nodes 220, . . . , 224 in a layer 210, . . . , 214 usually has no effect, however, on the calculations performed within the convolutional neural network 200 as such, because these are given solely by the structure and the weights of the edges.

For example, a convolutional layer 211 is characterized in that the structure and the weights of the ingoing edges form a convolution operation based on a certain number of kernels. For example, the structure and the weights of the ingoing edges are selected such that the values x(n)k of the nodes 221 in the convolutional layer 211 are calculated as a convolution x⁽ⁿ⁾ₖ=Kₖ*x⁽ⁿ⁻¹⁾ based on the values x⁽ⁿ⁻¹⁾ of the nodes 220 in the preceding layer 210, wherein the convolution * in the two-dimensional case is defined as follows:

x⁽ⁿ⁾ₖ[i,j]=(Kₖ*x⁽ⁿ⁻¹⁾)[i,j]=Σᵢ·Σⱼ·Kₖ[I′,j′]·x⁽ⁿ⁻¹⁾[i−I′,j−j′].

Here the k-th kernel Kₖ is a d-dimensional matrix (in this exemplary embodiment a two-dimensional matrix) which is usually small in comparison with the number of nodes 220, . . . , 224 (for example a 3×3 matrix or a 5×5 matrix). The implication of this for example is that the weights of the ingoing edges are not independent but are selected such that they create the stated convolution equation. For example, there are only 9 independent weights for a kernel that is a 3×3 matrix (each entry in the kernel matrix corresponds to an independent weight) regardless of the number of nodes 220, . . . , 224 in the respective layer 210, . . . , 214. For example, for a convolutional layer 211, the number of nodes 221 in the convolutional layer is equal to the number of nodes 220 in the previous layer 210 multiplied by the number of kernels.

If the nodes 220 in the previous layer 210 are arranged as a d-dimensional matrix, the use of a plurality of kernels can be interpreted as adding a further dimension (also called the “depth” dimension), with the result that the nodes 221 of the convolutional layer 221 are arranged as a (d+1)-dimensional matrix. If the nodes 220 in the previous layer 210 are already arranged as a (d+1)-dimensional matrix having a depth dimension, the use of a plurality of kernels can be interpreted as an expansion along the depth dimension, resulting in the nodes 221 of the convolutional layer 221 being arranged likewise as a (d+1)-dimensional matrix, but with the size of the (d+1)-dimensional matrix with regard to the depth dimension being larger than in the previous layer 210 by a factor given by the number of kernels.

An advantage of using convolutional layers 211 is that a spatially local correlation in the input data can be exploited by imposing a local connectivity pattern between nodes in adjacent layers, for example by each node being connected just to a small region of the nodes in the previous layer.

In the embodiment shown, the input layer 210 includes 36 nodes 220, which are arranged as a two-dimensional 6×6 matrix. The convolutional layer 211 comprises 72 nodes 221, which are arranged as two two-dimensional 6×6 matrices, with each of the two matrices being the result of convolving the values in the input layer with a kernel. Correspondingly, the nodes 221 of the convolutional layer 211 can be interpreted as arranged in a three-dimensional 6×6×2 matrix, wherein the last dimension is the depth dimension.

A pooling layer 212 can be characterized for example by the structure and the weights of the ingoing edges and by the activation function of its nodes 222, which form a pooling operation based on a non-linear pooling function f. For example, in the two-dimensional case, the values x(n) of the nodes 222 in the pooling layer 212 are calculated on the basis of the values x⁽ⁿ⁻¹⁾ of the nodes 221 in the previous layer 211 as:

x⁽ⁿ⁾[i,j]=f(x⁽ⁿ⁻¹⁾[id₁,jd₂], . . . ,x⁽ⁿ⁻¹⁾[id₁+d₁−1,jd₂+d₂−1]).

In other words, using a pooling layer 212 can reduce the number of nodes 221, 222 by replacing a number d1·d2 of adjacent nodes 221 in the previous layer 211 with a single node 222, which is calculated in the pooling layer as a function of the values of this number of adjacent nodes. For example, the pooling function f can be the max function, the average, or the L2 norm. For example, the weights of the ingoing edges are fixed for a pooling layer 212 and not modified by training.

The advantage of using a pooling layer 212 is that it reduces the number of nodes 221, 222 and the number of parameters. This leads to a reduction in the computational effort in the network and to a check on overfitting.

In the embodiment shown, the pooling layer 212 is a max pooling, in which four adjacent nodes are replaced by just one node, the value of which is the maximum of the values of the four adjacent nodes. The max pooling is applied to each d-dimensional matrix of the previous layer; in this embodiment, the max pooling is applied to each of the two two-dimensional matrices, resulting in a reduction in the number of nodes from 72 to 18.

A fully interconnected layer 213 may be characterized in that a plurality of, for example all, edges between the nodes 222 in the previous layer 212 and the nodes 223 in the fully interconnected layer 213 are present, and the weight of each of the edges may be adjusted individually.

In this embodiment, the nodes 222 in the layer 212 that precedes the fully interconnected layer 213 are represented both as two-dimensional matrices and additionally as non-related nodes (shown as a line of nodes, wherein the number of nodes has been reduced for better visualization). In this embodiment, the number of nodes 223 in the fully interconnected layer 213 equals the number of nodes 222 in the previous layer 212. Alternatively, the number of nodes 222, 223 may be different.

Furthermore, in this embodiment, the values of the nodes 224 in the output layer 214 are determined by applying the softmax function to the values of the nodes 223 in the previous layer 213. By applying the softmax function, the sum of the values of all the nodes 224 in the output layer equals 1, and all the values of all the nodes 224 in the output layer are real numbers between 0 and 1. For example if the convolutional neural network 200 is used for categorizing input data, the values of the output layer may be interpreted as the probability of the input data falling into one of the different categories.

A convolutional neural network 200 may also include a ReLU layer (acronym for “Rectified Linear Units”). For example, the number of nodes and the structure of the nodes contained in a ReLU layer is equal to the number of nodes and the structure of the nodes contained in the previous layer. For example, the value of each node in the ReLU layer is calculated by applying a rectifier function to the value of the corresponding node in the previous layer. Examples of rectifier functions are f(x)=max(0,x), the hyperbolic tangent function, or the sigmoid function.

For example, convolutional neural networks 200 may be trained on the basis of the backpropagation algorithm. Regularization methods may be employed in order to avoid overfitting, for example dropout of nodes 220, . . . , 224, stochastic pooling, the use of artificial data, weight decay based on the L1 or L2 norm, or max norm constraints.

FIG. 5 is used to illustrate an example of a method for providing a trained function for the output of correction data. In S110, training reference measurement data is provided, wherein at least part of the training reference measurement data is generated from magnetic resonance signals acquired by a plurality of receive antennas 27 of the local coil 26 by the magnetic resonance apparatus 10.

In S120, training image measurement data is provided, wherein the training image measurement data is generated from magnetic resonance signals acquired by the plurality of receive antennas 27 of the local coil 27 by the magnetic resonance apparatus 10.

In 130, training target image measurement data is generated by applying a correction algorithm to the training image measurement data. In S140, the training target image measurement data is provided.

In S150, the trained function is trained on the basis of the training reference measurement data and the training image measurement data as the training input data and the training target image measurement data as the training output data.

In S160, the trained function for the output of the correction data is provided.

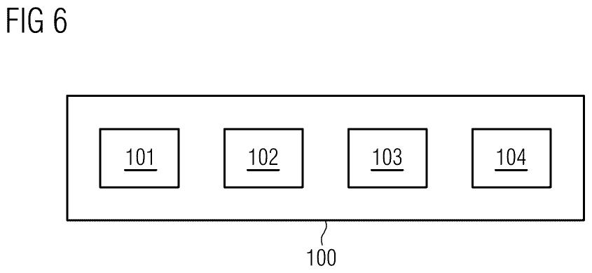

FIG. 6 depicts schematically a generation unit 100 for generating an intensity-corrected magnetic resonance representation.

FIG. 6 includes a first input interface 101 for receiving reference measurement data, wherein at least part of the reference measurement data is generated from magnetic resonance signals acquired by a plurality of receive antennas 27 of the local coil 26 by the magnetic resonance apparatus 10. The generation unit 100 includes a second input interface 102 for receiving image measurement data, wherein the image measurement data is generated from magnetic resonance signals acquired by the plurality of receive antennas 27 of the local coil 26 by the magnetic resonance apparatus 10. In addition, the generation unit 100 includes a calculation unit 103 for applying a trained function to the reference measurement data and the image measurement data, wherein the correction data is generated as output data, and includes an output interface 104 for the output of the correction data.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A computer-implemented method for generating an intensity-corrected magnetic resonance representation, comprising:
providing reference measurement data, wherein at least part of the reference measurement data is generated from magnetic resonance signals acquired by at least one receive antenna of at least one local coil by a magnetic resonance apparatus in accordance with a reference magnetic resonance sequence;
providing image measurement data, wherein the image measurement data is generated from magnetic resonance signals acquired by the at least one receive antenna of the least one local coil by the magnetic resonance apparatus in accordance with an image magnetic resonance sequence;
applying a function trained by a machine learning algorithm to the reference measurement data and the image measurement data as input data of the trained function;
providing correction data as output data of the trained function, wherein the correction data describes an instrumentation-induced intensity inhomogeneity of the image measurement data; and
generating the intensity-corrected magnetic resonance representation based on the image measurement data and the correction data.

2. The method of claim 1, wherein at least part of the reference measurement data is generated from magnetic resonance signals acquired by at least one receive antenna of a body coil that is fixedly integrated in the magnetic resonance apparatus.

3. The method of claim 1, wherein the reference magnetic resonance sequence is configured to bring about a neutral contrast in the reference measurement data.

4. The method of claim 1, wherein the image measurement data has an image coordinate system, wherein the method further comprises:
providing initial reference measurement data, which has a reference coordinate system,
wherein providing of reference measurement data comprises:
transforming the initial reference measurement data from the reference coordinate system into the image coordinate system.

5. The method of claim 1, wherein the reference measurement data is combined data, that is combined from individual measurement data, in each case acquired by the at least one receive antenna of the at least one local coil by the magnetic resonance apparatus in accordance with the reference magnetic resonance sequence.

6. The method of claim 1, wherein the trained function is based on a convolutional neural network.

7. The method of claim 6, wherein the convolutional neural network comprises a u-net architecture.

8. The method of claim 1, wherein the function is trained by:
providing training reference measurement data, wherein at least part of the training reference measurement data is generated from magnetic resonance signals acquired by the at least one receive antenna of at least one local coil by a magnetic resonance apparatus;
providing training image measurement data, wherein the training image measurement data is generated from magnetic resonance signals acquired by the at least one receive antenna of the at least one local coil by the magnetic resonance apparatus;
providing training target image measurement data, wherein the training target image measurement data is training image measurement data corrected by a correction algorithm; and
training the trained function based on the training reference measurement data and the training image measurement data and the training target image measurement data.

9. A computer-implemented method for providing a trained function for an output of correction data, the method comprising:
providing training reference measurement data, wherein at least part of the training reference measurement data is generated from magnetic resonance signals acquired by the at least one receive antenna of at least one local coil by a magnetic resonance apparatus;
providing training image measurement data, wherein the training image measurement data is generated from magnetic resonance signals acquired by the at least one receive antenna of the at least one local coil by the magnetic resonance apparatus;
providing training target image measurement data, wherein the training target image measurement data is training image measurement data corrected by a correction algorithm;
training the trained function based on the training reference measurement data and the training image measurement data and the training target image measurement data; and
providing the trained function for the output of the correction data.

10. A generation unit for generating an intensity-corrected magnetic resonance representation, the generation unit comprising:
a first input interface for receiving reference measurement data, wherein at least part of the reference measurement data is generated from magnetic resonance signals acquired by at least one receive antenna of at least one local coil by a magnetic resonance apparatus;
a second input interface for receiving image measurement data, wherein the image measurement data is generated from magnetic resonance signals acquired by the at least one receive antenna of the least one local coil by the magnetic resonance apparatus;
an output interface for the output of correction data; and
a calculation unit for applying a trained function to the reference measurement data and the image measurement data, wherein the correction data is generated as output data.
